(19) United States
(12) Patent Application Publication
(10) Pub. No.: US 2024/0012960 A1
(43) Pub. Date: Jan. 11, 2024

(54) Magnetic Resonance Tomography System Modeling

(71) Applicant: Siemens Healthcare GmbH, Erlangen (DE)

(72) Inventor: Dieter Ritter, Fürth (DE)

(73) Assignee: Siemens Healthcare GmbH, Erlangen (DE)

(21) Appl. No.: 18/218,161

(22) Filed: Jul. 5, 2023

(30) Foreign Application Priority Data
Jul. 5, 2022 (DE) 10 2022 206 850.5

(51) Int. Cl. G06F 30/20; G01R 33/56

(52) U.S. Cl. CPC G06F 30/20; G01R 33/5608

(57) ABSTRACT

An apparatus for modeling a magnetic resonance tomography system, designed to provide a digital twin of the magnetic resonance tomography system, wherein the digital twin includes pre-defined interfaces corresponding to the interfaces between individual components of the magnetic resonance tomography system.

### TECHNICAL FIELD

The present disclosure relates to an apparatus and a computer-implemented method for modeling a magnetic resonance tomography system. The present disclosure further relates to the apparatus for training an evaluating system for a magnetic resonance tomography system.

### BACKGROUND

Diagnostic imaging methods are of great significance in modern medicine. Such a diagnostic imaging method is, for example, magnetic resonance tomography or nuclear spin resonance tomography (MRT), or magnetic resonance imaging (MRI). Herein, slice images of a human or animal body can be generated, which enables, for example, an assessment of the organs and possibly morbid organ changes.

Due to the complexity and sometimes very high costs for individual components of such magnetic resonance tomography systems, further development, and improvement are associated with a high level of technical and financial expenditure. In particular, the creation of prototypes also demands a non-negligible timespan for producing such prototypes, apart from the high costs.

It is therefore desirable to minimize the requirements for the provision of real components in the course of the research and development of magnetic resonance tomography systems. It is desirable, in particular, for simulations of individual subcomponents of such a magnetic resonance tomography system to maintain existing interfaces between the respective subcomponents and thus to sustain the transitions and the associated signal and data exchange of the real systems.

### SUMMARY

The present disclosure provides an apparatus for modeling a magnetic resonance tomography system, an apparatus for training an evaluating system for a magnetic resonance tomography system, and a computer-implemented method for modeling a magnetic resonance tomography system

According to one aspect, an apparatus for modeling a magnetic resonance tomography system is provided. The apparatus is designed to provide a digital twin of the magnetic resonance tomography system. The digital twin comprises pre-defined interfaces which correspond to interfaces between individual components of the magnetic resonance tomography system.

According to a further aspect, a computer-implemented method for modeling a magnetic resonance tomography system is provided. The method emulates the magnetic resonance tomography system with a computer-implemented digital twin of the magnetic resonance tomography system. The digital twin comprises pre-defined interfaces which correspond to interfaces between individual components of the magnetic resonance tomography system.

According to a further aspect, an apparatus for training an evaluating system for image data from a magnetic resonance tomography system is provided. The evaluating system can classify the image data using a trained neural network. The evaluating system is trained using image data generated using data from an apparatus according to the aspects of the disclosure for modeling a magnetic resonance tomography system or the corresponding method according to the aspects of the disclosure.

The present disclosure is based upon the recognition that some of the individual components in a magnetic resonance tomography system are very complex. Therefore, producing such components is associated with high costs and a significant expenditure of time.

It is therefore a concept of the present disclosure to account for this recognition and provide an apparatus for modeling a magnetic resonance tomography system that emulates individual components of such a system as computer-implemented modules. Herein, the individual interfaces between the respective computer-implemented modules are provided in the same manner as they are also in corresponding real systems.

In this way, it is possible to read out or feed in the respective data and/or simulated measurement values in the same way as in the corresponding real systems. Based on this data at the interfaces between the individual modules, the system behavior can thus be analyzed in the same way as would also be the case in a real system based on hardware components. In this way, a complete digital twin of a magnetic resonance tomography system is created. By simulating the individual components at the interfaces between these components, this digital twin enables an analysis that is equivalent to examinations of real systems.

This way, firstly, the costs for research and development on magnetic resonance tomography systems can be significantly reduced since corresponding simulation units can emulate the complex and expensive components. Furthermore, modifications can also be carried out rapidly by way of corresponding parameterization of the individual simulation units without complex changes to real hardware having to be carried out for this or possibly completely new hardware components needing to be produced.

According to one embodiment, the apparatus for modeling the magnetic resonance tomography system comprises a plurality of modeling units and a scanner module. Each of the plurality of modeling units can be designed to provide output data of a component of the magnetic resonance tomography system as model data. The scanner module is designed to receive the model data from the plurality of modeling units. The scanner module is also designed to calculate the magnetic fields of a field generation unit of the magnetic resonance tomography system. In particular, the magnetic fields can be calculated using the model data provided. Furthermore, the scanner module is designed to provide output signals of the field generation unit using the calculated magnetic fields. The data exchange between the modeling units and the scanner module occurs using pre-defined interfaces. By this means, the functions and the signal patterns for driving the field generation unit and generating the output signals by way of the field generation unit can be emulated.

The field generation unit (FGU) is the totality of the components provided for generating the magnetic fields and/or receiving and processing the magnetic fields. The field generation unit can comprise, for example, a main magnet coil, for example in the form of a superconducting coil for generating a main magnetic field. Accordingly, the components for cooling this superconducting coil can also be part of the field generation unit. By way of this coil, a main magnetic field can be induced in the tube itself along a tube axis.

Furthermore, the field generation unit can comprise three mutually independent gradient coils in the X, Y, or Z direction. These gradient coils are meaningful, in particular, for position encoding. In addition, the field generation unit can comprise a transmitter coil which serves as a high-frequency transmitter for the high-frequency waves needed for imaging. Furthermore, a receiving coil that serves, for example, as a sensitive high-frequency receiver can be provided in the field generation unit.

Apart from the coils mentioned, by way of the field generation unit, further components can also be included, which can serve, for example, for driving the coils and/or for evaluating the signals provided by the coils. This can comprise, for example, driver stages for preparing electric currents to the coils for generating the magnetic fields. In addition, control components can be provided in the field generation unit, such as required in relation to generating and evaluating the magnetic fields. However, it should be understood that the field generation unit can, in principle, comprise, in addition to the components explicitly mentioned herein, any further components related to the generation of magnetic fields and/or the receiving and preparation of the receiving signals.

According to one embodiment, the apparatus for modeling a magnetic resonance tomography system further comprises an evaluation unit. The evaluation unit is designed to receive output signals prepared by the scanner module. Further, the evaluation unit is designed to generate image data using the output signals received from the scanner module. The data exchange between the scanner module and the evaluation unit takes place using pre-defined interfaces. By this means, the postprocessing of output signals from the field generation unit for generating the image data can also be emulated.

According to one embodiment, the pre-defined interfaces correspond to a real magnetic resonance tomography system's corresponding data interfaces or electrical interfaces. The interfaces between individual modules of the computer-implemented digital twin thus represent the respective interfaces of an emulated real system. This enables, firstly, the analysis of the data and/or signals to these interfaces. Furthermore, corresponding testing or checking signals and/or data can be fed in at these interfaces if needed. By this means, individual components can be analyzed in a targeted manner.

According to one embodiment, the apparatus for modeling a magnetic resonance tomography system comprises a model data store. The model data store is designed to store model data. At least one of the modeling units is designed to read out model data from the model data store and provide the read-out model data. Stored model data enables the rapid provision of the required model data. In addition, the model data stored in this way can also be provided lastingly. By this means, in different configurations, the identical model data is used to compare dual configurations with one another. In addition, using the stored model data also enables reproducible results.

According to one embodiment, the model data stored in the model data store comprises scan data and/or protocols from corresponding components of a magnetic resonance tomography system. The system behavior of real scenarios can be emulated in the digital twin using scan or protocol data. In particular, by this means, the digital twin can also be compared with the corresponding real system.

According to one embodiment, at least one of the modeling units comprises a user interface. The user interface is designed to receive user interfaces. Further, at least one modeling unit is designed to generate modeling data using the received user inputs. In this way, a user-defined configuration can take place.

According to one embodiment, the plurality of modeling units comprises a modeling unit for modeling scan objects, a modeling unit for modeling electric and/or magnetic systems, a modeling unit for modeling external influences, and/or a modeling unit for providing previously stored scan data or scan sequences. By this means, the individual properties can be individually adapted and/or modeled.

According to one embodiment, the scanner module is designed to calculate the magnetic fields of the field generation unit using a Bloch simulation. In a Bloch simulation of this type, the magnetic fields of the field generation unit can be calculated based on the so-called Bloch equation. This Bloch equation describes the temporal development of a spin system in the magnetic field. This way, the magnetic fields in the field generation unit can be emulated very well.

According to one embodiment, the scanner module is designed to calculate the magnetic fields of the field generation unit using a plurality of mutually independent terms. Therein, either previously scanned, simulated, model or null values can be selected for each term. Using a plurality of independent terms enables an orthogonalization of the influences of the respective terms and/or the properties associated with the respective terms. In this way, individual influences such as disturbances or suchlike can easily be associated with the corresponding terms and thus with the sources of these influences.

According to one embodiment, the independent terms comprise
(1) a vector of the magnetic field for each spin,
(2) a term for the non-linear gradient of the magnetic field,
(3) a term for inhomogeneity of the main magnetic field,
(4) a Maxwell term,
(5) a term for magnetic susceptibility,
(6) a term for an eddy current field,
(7) a term for an external magnetic interference field,
(8) a term for a shim coil;
(9) a term for the sensitivity of the receiving coils and/or
(10) a term for external high-frequency disturbances.

According to one embodiment, the apparatus for modeling a magnetic resonance tomography system comprises a storage device. The storage device is designed to store and provide previously established measured values, simulated values, and/or model values for the individual independent terms. By this means, the stored data can be easily used. This enables reproducible results. Furthermore, different configurations can also easily be compared with one another based on the stored data.

The above embodiments and developments can be combined as desired, if useful. Further embodiments, developments, and implementations of the aspects of the disclosure also include not explicitly mentioned combinations of features of the disclosure described above or below in relation to the exemplary embodiments. In particular, a person skilled in the art would also add individual aspects as improvements or enhancements to the respective basic forms of the aspects of the disclosure.

### BRIEF DESCRIPTION OF THE DRAWINGS

Further features and advantages of the aspects of the disclosure are explained below, referring to the drawings, in which:

FIG. 1 shows a schematic representation of a block diagram to illustrate the basic principle of a magnetic resonance tomography system;

FIG. 2 shows a schematic representation of a block diagram to illustrate the basic principle of an apparatus for modeling a magnetic resonance tomography system according to one embodiment;

FIG. 3 shows a schematic representation of an evaluation system of a magnetic resonance tomography system according to one embodiment; and

FIG. 4 shows a flow diagram forming the basis for a method for operating a magnetic resonance tomography system according to one embodiment.

### DETAILED DESCRIPTION

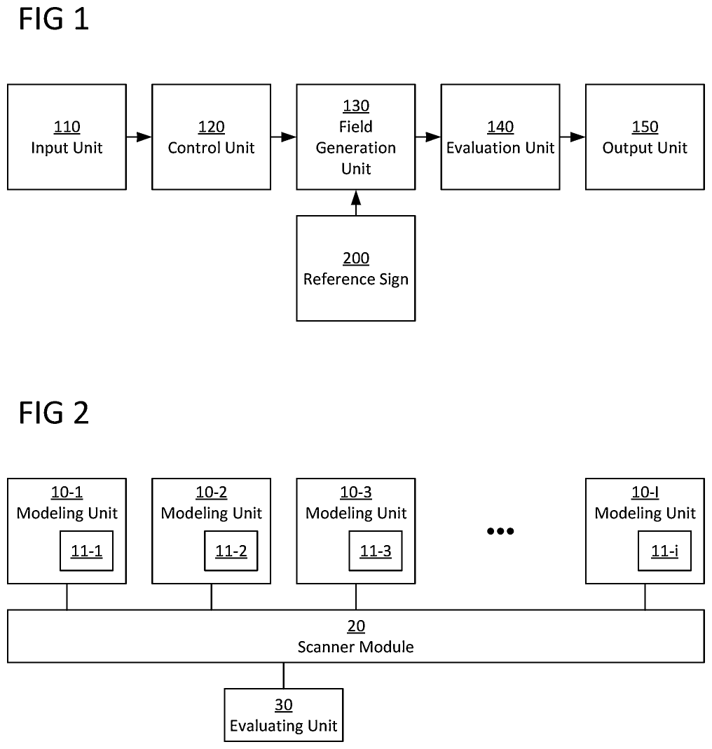

FIG. 1 shows a schematic representation of a block diagram to illustrate the basic principle of a magnetic resonance tomography system. For example, a user can plan an examination on an input unit 110 and specify parameters, examination sequences, and further details. After that, from the user inputs, a control unit 120 can generate control signals for driving a field generation unit (FGU) 130 and provide these control signals to the magnetic field unit 130. After that, by way of the magnetic field 130, a sample to be examined, for example, a body part and/or an organ of a living being, in particular a human or an animal, can be scanned. The properties of the sample to be scanned are represented by the reference sign 200.

Herein, the field generation unit 130 provides output signals which can be received and evaluated by evaluation unit 140. The evaluation unit 140 generates image data from the signals from the field generation unit 130, which can be displayed on the output unit 150 and/or output. Since, however, the basic principle of such a magnetic resonance tomography system is regarded as being known, a more detailed explanation is omitted here.

FIG. 2 shows a schematic representation of a block diagram of apparatus 1 for modeling a magnetic resonance tomography system according to one embodiment. Apparatus 1 for modeling the magnetic resonance tomography system forms a digital twin of a corresponding real magnetic resonance tomography system. Therein, the individual components of the magnetic resonance tomography system can each be formed as computer-implemented simulation modules. In particular, the interfaces can thereby be implemented between the individual computer-implemented simulation modules equivalent to the respective interfaces of the function modules of the real magnetic resonance tomography system. In this way, the exchange of data and signals between the individual function modules in the computer-implemented digital twin corresponds to the exchange between the respective components of the real magnetic resonance tomography system. Thus, the data and/or signals between the individual function modules can be acquired and evaluated. It is also possible, where relevant, to feed desired, specified data and/or signals to the respective interfaces. In particular, using this type of structure of a computer-implemented digital twin, a system is realized that offers far greater flexibility and varied possibilities than a completely closed black box system.

For modeling the magnetic resonance tomography system, apparatus 1 can comprise a plurality of modeling units 10-i. Each of these modeling units 10-i can herein provide, for example, data that corresponds to the output of a component in a real magnetic resonance tomography system. For example, using such modeling units 10-i, individual components of the magnetic resonance tomography system can each be emulated digitally. In this way, the functions and properties among corresponding components of the magnetic resonance tomography system can be simulated.

Further, the apparatus 1 for modeling the magnetic resonance tomography system can comprise a scanner module 20. This scanner module 20 can receive the model data from the modeling units 10-i and, using the received model data, can calculate magnetic fields as they occur, particularly in a field generation unit (FGU) of a magnetic resonance tomography system. Based on these calculated magnetic fields, the scanner module 20 can calculate and provide the output signals of such a field generation unit.

Further, the apparatus 1 for modeling the magnetic resonance tomography system can comprise an evaluation unit 30. This evaluation unit 30 can receive the output signals provided by the scanner module 20 and generate image data using the received output signals from the scanner module 20. The image data generated in this way corresponds to image data as can be obtained from a corresponding real magnetic resonance tomography system.

This way, a digital map, a so-called digital twin of a magnetic resonance tomography system, can be formed. Herein, pre-defined interfaces can be provided for the data exchange between the modeling units 10-i, the scanner module 20, and the evaluation unit 30. In particular, these pre-defined interfaces can each represent corresponding interfaces in a real magnetic resonance tomography system. In other words, the data exchange in the digital twin takes place in the same manner as data and/or signals are exchanged in a real system emulated by the digital twin. If, for example, data and/or digital information is exchanged between the components of a magnetic resonance tomography system, then at the interfaces between the individual components in apparatus 1, for modeling the magnetic resonance tomography system, identical data and/or digital signals can be exchanged. If, in a real magnetic resonance tomography system, a coupling takes place between components in which, for example, electrical signals are exchanged, then in the corresponding components of apparatus 1 for modeling the magnetic resonance tomography system, these electrical signals are also emulated at the corresponding interfaces.

Accordingly, this digital data and/or information or the emulated electrical signals are then available at the respective interfaces of the digital twin. By this means, it is firstly possible to analyze and/or evaluate this data or these signals at the interfaces to draw conclusions about the system behavior of the emulated magnetic resonance tomography system. Secondly, through the use of the pre-defined interfaces, which correspond to interfaces of a real magnetic resonance tomography system, it is also possible to observe the individual components between these interfaces independently of one another and also possibly, if needed, to adapt or exchange them individually.

In individual modeling units 10-i, for example, a model data store 11-i can be provided. In such model data stores 11-i, values or sequences previously acquired with measuring technology can be stored and, during a simulation, can be read out from the respective modeling units 10-i and provided to the respective interfaces. For example, data and/or values from corresponding real systems can be used for a simulation.

Apart from previously acquired measurement values, it is also possible to store values and/or data from a previous modeling or simulation in the corresponding model data store 11-i and, if needed, read it out and provide it at the corresponding interfaces. Therefore, it is not required for each new pass of a magnetic resonance tomography system simulation to always calculate all the model data afresh.

For example, the modeling units 10-i can comprise the modeling of components or assemblies of a magnetic resonance tomography system. Furthermore, by way of the modeling units 10-i, data can also be provided from objects and/or samples to be examined by way of a magnetic resonance tomography system to be modeled. Such objects can be, in particular, parts of a human or animal body, for example, modeling of individual organs in a body. Apart from purely statistically modeled objects, dynamic modelings are also possible. In this way, for example, the flow of blood through an organ or suchlike can be emulated.

Further, in the modeling, any influences and/or disturbances can also be taken into account. Thus, for example, by way of corresponding modeling units, disturbances can be emulated by way of external magnetic fields, high-frequency signals, or suchlike, and these modeled disturbances can also be included in the simulation of the magnetic resonance tomography system.

The substantial core of the simulation of a magnetic resonance tomography system then takes place by calculating the magnetic fields of a field generation unit (FGU) of the corresponding magnetic resonance tomography system. For this purpose, firstly, the simulation process can include the model data provided by the modeling units 10-i, such as control sequences, modeling of the objects to be examined, interference effects, etc. In this way, the calculation of the magnetic fields and the output signal of the field generation unit resulting therefrom also takes account of the corresponding configuration and/or parameterization of the field generation unit to be simulated. This calculation of the magnetic fields and the corresponding output signals herein takes place using the scanner module 20.

The calculation of the magnetic fields and the output signal derived therefrom the field generation unit can take place, in particular, using a so-called Bloch simulation. The Bloch equation underlying such a Bloch simulation describes the temporal development of a spin system in the magnetic field.

The magnetic field B for each spin at the spatial position r(x,y,z) at the time point t can be described as:

$$\overline{B} ( \overline{r} , t ) = ( \begin{matrix}{B}_{1 , x} ( \overline{r} , t ) \\ {B}_{1 , y} ( \overline{r} , t ) \\ {B}_{0}^{r e s} ( \overline{r} , t )\end{matrix} ) \qquad ( Equation 1 )$$

where B₁ represents the magnetic field with (B_{1,x}+iB_{1,y}).

Further,

B₀^{res}(r̅,t)=Gₓ(t)x+G_{y}(t)y+G_{z}(t)z+ΔB₀(r̅)+B_{CC}(r̅,t)+B_{S}(r̅)+B_{EC}(r̅,t)+Bₑₓₜ(r̅,t)+Bₛₕᵢₘ(r̅) (Equation 2)
wherein Gₓ(t)x+G_{y}(t)y+G_{z}(t)z defines the term for the non-linear gradient of the magnetic field,
ΔB₀(r̅) defines the inhomogeneity of the main magnetic field B₀,
B_{CC}(r̅,t) represent the Maxwell terms,
B_{S}(r̅) defines the magnetic susceptibility,
B_{EC}(r̅,t) represents the eddy current field,
Bₑₓₜ(r̅, t) defines an external magnetic interference field, and
Bₛₕᵢₘ(r̅) represents the magnetic field of the shim coils.

The can be included in the Bloch equation:

$$\frac{d \overline{m} ( \overline{r} )}{d t} = γ \overline{m} ( \overline{r} ) \times \overline{B} ( \overline{r} , t ) + ( \begin{matrix}- {m}_{x} / {T}_{2} \\ - {m}_{y} / {T}_{2} \\ ( {m}_{z 0} - {m}_{z} ) / {T}_{1}\end{matrix} ) \qquad ( Equation 3 )$$

wherein m represents the spin vector with the transverse magnetization m_{x,y} and the longitudinal magnetization m_{z}.
m_{z0} stands for the magnetization equilibrium,
γ for the gyromagnetic ratio,
T₁ stands for the longitudinal relaxation, and
T₂ stands for the transverse relaxation.

From this, finally, the received signals of the field generation unit can be determined:

$${s}_{n} ( t ) = {\sum }_{r} {c}_{n} ( \overline{r} ) {m}_{x y} ( \overline{r} , t ) + {E}_{n} ( t ) \qquad ( Equation 4 )$$

wherein sₙ represents the receiver signal of the n-th receiver coil,
cₙ represents the sensitivity of the n-th receiver coil,
m_{x,y} represents the transverse magnetization of a voxel, and
Eₙ represents external high-frequency disturbances for the n-th receiver coil.

By way of such modeling for calculating the magnetic fields in the field generation unit of a magnetic resonance tomography system, the resulting receiver signals of the individual receiver coils can thus be calculated. From the receiver signals thus ascertained, the output signals corresponding thereto of the field generation unit can then be determined. These output signals can be provided in any desired suitable manner as output values of the scanner module 20. In particular, for example, by way of the scanner module 20, values of output signals can be provided, representing the output values of a corresponding real field generation unit. In this way, using the scanner module 20, the corresponding function in a magnetic resonance tomography system can be emulated.

Since for the simulation of the corresponding components in the magnetic resonance tomography system, in particular also by way of the scanner module 20, standardized interfaces can be used which preferably also correspond to the interfaces as they are found in real magnetic resonance tomography systems, the modeling of the magnetic resonance tomography system represents a real likeness to a very great extent. Therefore such modeling can also be designated a digital twin of such a magnetic resonance tomography system.

Such a digital twin, which also, in particular, can provide precise data relating to individual components of the corresponding real system, enables a very good analysis of the corresponding processes in the respective system. Thus, for example, the results of the digital twin can be compared with the real system's corresponding signals or system properties to verify the digital twin. In this way, the trustworthiness of the results from the digital twin can be enhanced.

Likewise, by way of the uniformity in the interfaces for input and output signals, it is also possible to feed to the corresponding interfaces data or signals that have been obtained from comparable real systems or have already been verified by comparable real systems.

The use of such a digital twin for modeling the processes in a magnetic resonance tomography system, therefore, makes it possible to analyze the processes in such a magnetic resonance tomography system by easy means, to study them and thereby also better understand them without the corresponding hardware components of the magnetic resonance tomography system having to be adapted for each modification. Rather, by adapting corresponding parameters in the respective module, for example, in the scanner module 20, the modeling units 10-i, or the evaluation unit 30, a modification can be undertaken by simple means. After using the newly parameterized and/or configured model, the effects of this modification can be ascertained and analyzed. Firstly, a modification of this type in the modeling can be undertaken significantly more rapidly than a complex adaptation in the real hardware. Furthermore, such a modification in the modeling is also significantly more economical to realize that a modification in the real hardware, possibly requiring the production of new hardware components.

The model data for the processing in apparatus 1 of this type for modeling the magnetic resonance tomography system can, as already set out above, be generated and provided in any desired manner by the modeling units 10-i. For example, for this purpose, real scan data or scan sequences from corresponding systems can be obtained and stored in a respective store 11-i of the modeling units 10-i. Further, in place of scan data or sequences obtained by real measurement technology, corresponding data or sequences can be calculated in advance based on corresponding modeling and stored in store 11-i. For this purpose, it is, for example, also possible that a user specifies and/or parameterizes a model using a corresponding user interface, and the respective modeling unit 10-i calculates the model data based on the user specifications. The calculated model data can either be stored initially in a store 11-i or output directly via the respective interface to the further modules, for example, the scanner module 20.

Apart from modeling the system components for driving the magnetic resonance tomography system, the model data can also comprise model data for the objects to be examined. Such model data can be obtained, for example, from previous actual scans of a magnetic resonance tomography system. In addition, it is also possible to use model data for the objects to be examined and from such a modeled object. For this purpose, for example, a human's or animal's body parts or organs can be modeled accordingly. Apart from purely statistical objects, the model data can also comprise model data for dynamic processes in the objects being examined. Thus, the model data can also comprise, for example, sequences in which dynamic processes take place within the object to be examined. For example, a fluid flow through the object being examined can be modeled. For example, the blood flow through an organ during an examination can be emulated. However, any other dynamic processes for examining an object are naturally also possible. The model data used herein can be provided, for example, in a store such as a database or suchlike. Thus, the desired model data can be read from this store and used for the respective simulation.

The output data of the scanner module 20 can be output to an evaluation unit 30 for evaluation. This evaluation unit 30 can then generate image data by the data provided from the scanner module 20. The generation of image data therein takes place in the same way as in creating image data in a real magnetic resonance tomography system. Since, for the exchange of the data and signals between the individual components in apparatus 1 for modeling the magnetic resonance tomography system, standardized interfaces are used which can correspond to the interfaces of a real magnetic resonance tomography system, herein the output and passing on of the data from the scanner module 20 to an evaluation unit 30 takes place similarly to the data exchange in a real system. In particular, for example, an evaluation unit 30, which is used in corresponding real systems, can also be used to evaluate the data from the scanner module 20.

For example, based on the image data generated by evaluation unit 30, the system behavior of a magnetic resonance tomography system emulated by apparatus 1 for modeling a magnetic resonance tomography system can be analyzed. Thus, for example, disturbances, unsharpness, artifacts, or suchlike can be assessed in the resulting image data. In particular, by comparing the image data with different parameterizations and/or properties in the model data or the configuration of the scanner module 30, conclusions can be drawn concerning its influence in relation to the resulting image data. In particular, if during the modeling of the magnetic resonance tomography system for the data from the examined object, in each case, the same data is called upon, then influences from changes to the examined object between the individual passes can also be prevented. Thus, deviations due to changes in the examined object can also be precluded during the assessment of the different configurations of the modeled magnetic resonance tomography system.

Conversely, with the same settings for modeling the magnetic resonance tomography system and different datasets for the object to be examined, the influences of the object to be examined on the operating behavior and the resulting image data can also be analyzed very precisely.

For analyzing the system behavior, identifying disturbances or faults, or any other investigations, the modeling and/or parameterization in apparatus 1 for modeling the magnetic resonance tomography system can be adapted in a targeted manner. Apart from specifications for the properties of the hardware components such as, for example, the coils, amplifiers, signal generators, etc. used, the individual subterms of the Bloch system can also be adapted in a highly targeted manner for calculating the magnetic fields in the scanner module 20. Herein, in the context of the present disclosure, it has been established that the output signals of the field generation unit of a magnetic resonance tomography system are substantially influenced by ten mutually independent terms. These ten terms are the terms (i) to (x) explained in more detail below, which have already been described in relation to the explanation of the Bloch equation.

The first term (i) therein defines the x- and y-components of the magnetic field vector for each spin, particularly the components for the magnetic field in the longitudinal direction and the lateral direction (x- and y-directions). The components for the remaining z-direction can herein typically not be established.

The further terms (ii)-(viii) represent the sum terms for determining the resulting magnetic field. In detail, these are
(ii) Gₓ(t)x+G_{y}(t)y+G_{z}(t)z the term for the non-linear gradient of the magnetic field,
(iii) ΔB₀(r̅) the inhomogeneity of the main magnetic field B₀,
(iv) B_{CC}(r̅,t) the Maxwell terms,
(v) B_{S}(r̅) the magnetic susceptibility,
(vi) B_{EC}(r̅,t) the eddy current field,
(vii) Bₑₓₜ(r̅,t) an external magnetic interference field, and
(viii) Bₛₕᵢₘ(r̅) the magnetic field of the shim coils.

As set out above, the output signals of the individual receiving coils can be calculated from the magnetic field calculated on this basis with the aid of the Bloch equation.

In the calculation of these output signals, the following two components additionally influence the image data:
(ix) cₙ represents the sensitivity of the n-th receiver coil, and
(xx) m_{x,y} represents the transverse magnetization of a voxel (3D image element).

Based on the recognition that the ten terms above (i) to (x) can be considered independently of one another, it is also possible, in the calculation of the output signals for the field generation unit, to take account of each of these ten terms (i) to (x) individually. In particular, these ten terms (i) to (x) can be activated individually and separately (i.e., provided with specific terms) or deactivated (i.e., provided with an inactive value). As an inactive value, for example, 0 can be selected for a summand or 1 for a factor.

By way of targeted activation and deactivation of individual terms, an influence of the respective terms on the result of the magnetic resonance tomography system, particularly on the output signals of the field generation unit or the resulting image data, can therefore be established. If, for example, a disturbance is contained in an active term in the resulting image data, which disappears or becomes smaller when the respective term is deactivated, then it can be concluded therefrom that this term and the components associated with it in the magnetic resonance tomography system contribute to a disturbance of this type. Therefore, a possible error source can very rapidly be localized and identified.

For activating the respective terms (i) to (x), data from previous real scans, data from simulations, or model data can be used for the individual terms. Thus, for example, by way of the use of real scan data, in the first place, scenarios that match corresponding real systems can very easily be reproduced. In particular, if, for example, for some of the terms, real scan data is used and therein one of the terms is deactivated in each case, then in this way, a possible disturbance source or fault source can be identified very easily without complex and expensive interventions into a hardware test system having to be made.

Furthermore, simulations or modeling allow test conditions to be adjusted without requiring an expensive and complex structure of the real hardware. The individual data, signal values, operating sequences, etc., can now be calculated in advance and placed in a suitable store. Thus, the prepared simulated or modeled data and previously determined scan values can be made available in such a store and can be used multiple times if needed.

Thus, firstly the costs for procuring and producing the hardware components can be spared and/or minimized. In addition, longer waiting times required for the production of special hardware components, particularly prototypes, can also be spared. In addition, the described digital twin of a magnetic resonance tomography system can be realized as a computer-implemented solution with a significantly reduced space requirement than is the case for constructing one or more real test constructions for a magnetic resonance tomography system.

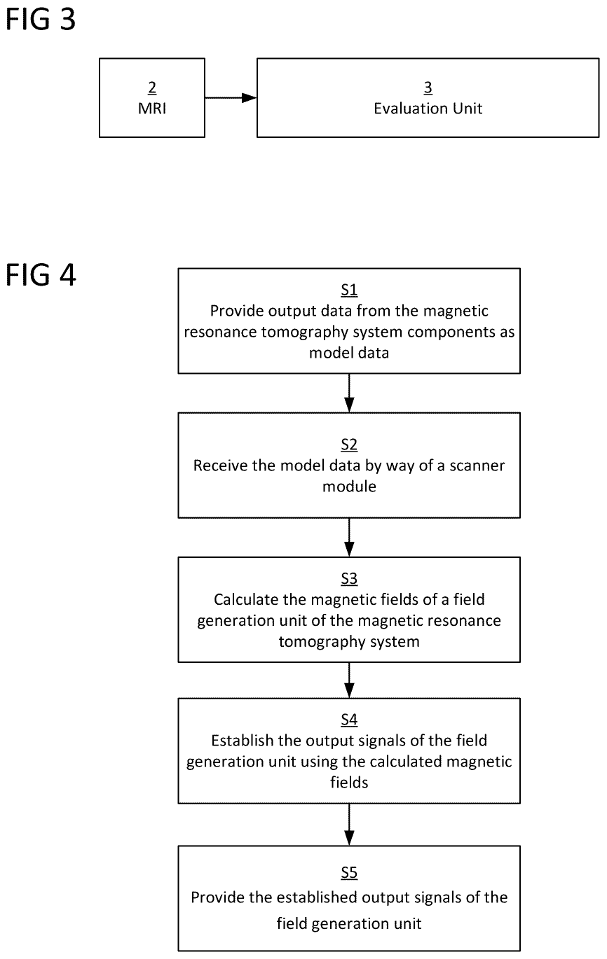

The output data of a magnetic resonance tomography system, particularly the image data provided by the evaluation unit 30, can be used, apart from the above-described analysis of the overall system, for training an automated evaluation system. FIG. 3 shows, by way of example, a small block diagram of such an evaluation system. Therein, image data of a magnetic resonance tomography system 2 can be provided to an evaluation unit 3. The evaluation unit 3 can then identify, for example, characteristic features in the image data using any desired methods and marking them in the image data. It is likewise possible to analyze the image data and, using identified characteristic features, to indicate a possible diagnosis. For the evaluation of the image data, for example, methods based upon artificial intelligence such as neural networks or suchlike can be used.

Typically, large quantities of datasets are required for the configuration and/or the training of such systems. The datasets required for this, for example, in the form of image data with corresponding information regarding the properties contained in the image data, can also be generated by way of a previously described apparatus 1 for modeling a magnetic resonance tomography system.

In particular, by using known data for the modeling of the objects to be examined, properties can be specifically set in the objects to be examined. Accordingly, the resulting image data thereto can be linked to these properties. In this way, using the modeling for the magnetic resonance tomography system, it is possible to generate image data in which the objects to be examined have known pre-determined properties. Thus, the resulting image data can be tagged in a simple manner. Since such a generation of image data can also be carried out fully using the digital twin of a magnetic resonance tomography system, and therefore no cost-intensive hardware is required, in this way, image data can be generated very cost-effectively in a large quantity and with many variations. The image data thus generated can be used, for example, to train automated systems with artificial intelligence, for example, neural networks or suchlike.

For this purpose, for example, the model data for the objects to be examined can also be generated and/or modified in an automated way, and the resulting image data for this can be automatically tagged with the corresponding properties. For example, the data linked in this way can be stored in a storage device. The data can then be read out from this storage device to train the learning system. To create the training data, it is possible to provide a user interface via which a user can specify particular properties or modifications of the objects to be examined. On the basis thereof, an automated generation of the required image data can subsequently be carried out for training the automated evaluation system.

FIG. 4 shows a flow diagram illustrating the principle underlying an embodiment of a computer-implemented method for modeling a magnetic resonance tomography system according to one embodiment. By way of such a method, a digital twin of a magnetic resonance tomography system can be emulated. In particular, therein, pre-defined interfaces can be provided which correspond to interfaces between individual components of a real magnetic resonance tomography system.

The method can, in principle, comprise any desired steps as described above in relation to the corresponding apparatus. Similarly, the apparatus described above can comprise any desired components as set out below in relation to the method.

In step S1, output data from the magnetic resonance tomography system components can be provided as model data.

The model data provided can be received in step S2 by way of a scanner module.

In step S3, the scanner module can then calculate the magnetic fields of a field generation unit of the magnetic resonance tomography system.

In step S4, the output signals of the field generation unit are established using the calculated magnetic fields, and in step S5, the established output signals of the field generation unit are provided.

As stated above, the data exchange takes place for providing the output data from the components of the magnetic resonance tomography system to the scanner module using pre-defined interfaces.

Summarizing, the present disclosure relates to a digital twin of a magnetic resonance tomography system. The emulated magnetic resonance tomography system's individual components can also be realized through computer-implemented modules. Herein, in particular, pre-defined interfaces between the individual components are provided, representing corresponding interfaces of the real magnetic resonance tomography system to be modeled.

The various components described herein may be referred to as “units” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units or devices, as applicable and relevant, may alternatively be referred to herein as “circuitry,” “controllers,” “processors,” or “processing circuitry,” or alternatively as noted herein.

1. An apparatus for modeling a magnetic resonance tomography system, wherein the apparatus is designed to provide a digital twin of the magnetic resonance tomography system, and the digital twin has pre-defined interfaces corresponding to the interfaces between individual components of the magnetic resonance tomography system.

2. The apparatus as claimed in claim 1, wherein the pre-defined interfaces correspond to data interfaces or electrical interfaces of a real magnetic resonance tomography system.

3. The apparatus as claimed in claim 1, comprising:
a plurality of modeling units, each designed to provide output data of a component of the magnetic resonance tomography system as model data; and
a scanner module designed to receive the model data from the plurality of modeling units, to calculate magnetic fields of a field generation unit of the magnetic resonance tomography system, and to provide output signals of the field generation unit using the calculated magnetic fields,
wherein a data exchange between the modeling units and the scanner module takes place using the pre-defined interfaces.

4. The apparatus as claimed in claim 3, comprising:
an evaluation unit designed to receive the output signals provided by the scanner module and, using the received output signals from the scanner module, to generate image data,
wherein a data exchange between the scanner module and the evaluation unit takes place using the pre-defined interfaces.

5. The apparatus as claimed in claim 3, comprising:
a model data store designed to store model data,
wherein at least one of the modeling units is designed to read out model data from the model data store and to provide the read-out model data.

6. The apparatus as claimed in claim 5, wherein the model data stored in the model data store comprises scan data and/or protocols from corresponding components of a magnetic resonance tomography system.

7. The apparatus as claimed in claim 3,
wherein at least one of the modeling units comprises a user interface designed to receive user input, and
wherein the at least one modeling unit is designed to generate modeling data using the received user inputs.

8. The apparatus as claimed in claim 3, wherein the plurality of modeling units comprises a modeling unit designed to model scan objects, a modeling unit designed to model electric and/or magnetic systems, a modeling unit designed to model external influences, and/or a modeling unit designed to provide previously stored scan data or scan sequences.

9. The apparatus as claimed in claim 3, wherein the scanner module is designed to calculate the magnetic fields of the field generation unit using a Bloch simulation.

10. The apparatus as claimed in claim 3, wherein the scanner module is designed to calculate the magnetic fields of the field generation unit using a plurality of mutually independent terms, and wherein for each term, either previously measured values, simulated values, model values, or a null value is selectable.

11. The apparatus as claimed in claim 10, wherein the independent terms comprise:
(1) a vector of the magnetic field for each spin,
(2) a term for a non-linear gradient of the magnetic field,
(3) a term for an inhomogeneity of a magnetic main field,
(4) a Maxwell term,
(5) a term for magnetic susceptibility,
(6) a term for an eddy current field,
(7) a term for an external magnetic interference field,
(8) a term for a shim coil,
(9) a term for a sensitivity of the receiving coils, and/or
(10) a term for external high-frequency disturbances.

12. The apparatus as claimed in claim 1, comprising:
a storage device designed to store and provide previously established measured values, simulated values, and/or model values for the individual independent terms.

13. An apparatus for training an evaluation system for image data from a magnetic resonance tomography system, wherein the evaluation system classifies the image data using a trained neural network, and the evaluation system is trained using image data that has been generated using data from an apparatus for modeling a magnetic resonance tomography system as claimed in claim 1.

14. A computer-implemented method for modeling a magnetic resonance tomography system, wherein the method comprises emulating the magnetic resonance tomography system by way of a digital twin of the magnetic resonance tomography system, and the digital twin has pre-defined interfaces which correspond to interfaces between individual components of the magnetic resonance tomography system.

15. The method as claimed in claim 14, comprising:
providing output data from components of the magnetic resonance tomography system as model data;
receiving the provided model data by a scanner module;
calculating magnetic fields of a field generation unit of the magnetic resonance tomography system by the scanner module;
establishing output signals of the field generation unit using the calculated magnetic fields; and
providing the established output signals from the field generation unit,
wherein a data exchange takes place for providing the output data from the components of the magnetic resonance tomography system to the scanner module using the pre-defined interfaces.
